(19) United States
(12) Patent Application Publication
(10) Pub. No.: US 2024/0096739 A1
(43) Pub. Date: Mar. 21, 2024

(54) HEAT SPREADER AND ELECTRONIC COMPONENT DEVICE

(71) Applicant: SHINKO ELECTRIC INDUSTRIES CO., LTD., Nagano (JP)

(72) Inventor: Yoriyuki SUWA, Nagano (JP)

(21) Appl. No.: 18/460,959

(22) Filed: Sep. 5, 2023

(30) Foreign Application Priority Data
Sep. 21, 2022 (JP) 2022-150018

(51) Int. Cl. H01L 23/373; H01L 23/367

(52) U.S. Cl. CPC H01L 23/3736; H01L 23/367

(57) ABSTRACT

A heat spreader includes a metal substrate and a plating layer covering a surface of the metal substrate. Multiple depressions and multiple projections are alternately arranged in the surface of the metal substrate covered by the plating layer.

### CROSS-REFERENCE TO RELATED APPLICATION

This application is based upon and claims priority to Japanese Patent Application No. 2022-150018, filed on Sep. 21, 2022, the entire contents of which are incorporated herein by reference.

### FIELD

A certain aspect of the embodiments discussed herein is related to heat spreaders and electronic component devices.

### BACKGROUND

There have been semiconductor devices in which a semiconductor chip is flip-chip bonded onto a wiring substrate. According to such semiconductor devices, a heat spreader is disposed on the back side of the semiconductor chip to efficiently dissipate heat generated by the semiconductor chip (see Japanese Laid-open Patent Publication Nos. 2010-092977, 2011-134769 and 2022-085602).

### SUMMARY

According to an embodiment, a heat spreader includes a metal substrate and a plating layer covering a surface of the metal substrate. Multiple depressions and multiple projections are alternately arranged in the surface of the metal substrate covered by the plating layer.

The object and advantages of the invention will be realized and attained by means of the elements and combinations particularly pointed out in the claims.

It is to be understood that both the foregoing general description and the following detailed description are exemplary and explanatory and not restrictive of the invention, as claimed.

### BRIEF DESCRIPTION OF DRAWINGS

FIGS. 1A and 1B are diagrams illustrating a heat spreader according to a first embodiment; and

FIGS. 2A and 2B are sectional views of an electronic component device according to a second embodiment.

### DESCRIPTION OF EMBODIMENTS

In recent years, semiconductor chips that generate more heat have been used, which has created demands for heat spreaders with better heat dissipation performance.

According to an embodiment, it is possible to improve heat dissipation performance.

According to an embodiment, a heat spreader and an electronic component device that can improve heat dissipation performance are provided.

Embodiments of the present invention are explained with reference to the accompanying drawings. In the following description, the same elements or components are referred to using the same reference numerals, and a duplicate description thereof may be omitted.

### [a] First Embodiment

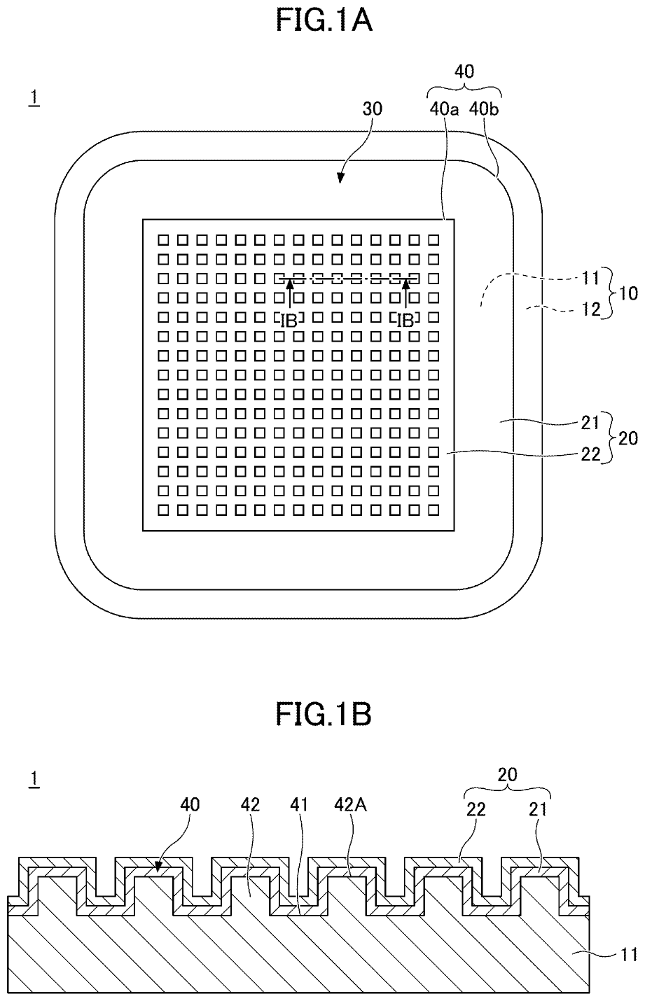

A first embodiment is described. The first embodiment relates to a heat spreader. FIGS. 1A and 1B are a plan view and a sectional view, respectively, of a heat spreader according to the first embodiment. FIG. 1B illustrates a section taken along the line IB-IB of FIG. 1A.

Referring to FIGS. 1A and 1B, a heat spreader 1 according to the first embodiment includes a metal substrate 10 and a plating layer 20.

The metal substrate 10 includes a flat plate part 11 and an annular protruding part 12. The protruding part 12 protrudes in the thickness direction of the flat plate part 11 from the periphery of the flat plate part 11. According to the first embodiment, for convenience, the direction in which the protruding part 12 protrudes from the periphery of the flat plate part 11 is defined as “upward direction.” The metal substrate 10 contains, for example, copper (Cu). The metal substrate 10 may be formed of copper material. The thickness of the metal substrate is, for example, approximately 2.5 mm or more and approximately 3.5 mm or less.

The flat plate part 11 has a planar shape of a rounded rectangle, for example. The protruding part 12 protrudes upward from the periphery of the flat plate part 11. An accommodating part 30 to accommodate a semiconductor chip is formed on and above the flat plate part 11 and inside the protruding part 12. That is, a space on and above the flat plate part 11 surrounded by the protruding part 12 serves as the accommodating part 30. The height of the protruding part 12 may be suitably determined according to the thickness of a semiconductor chip to be accommodated in the accommodating part 30.

The flat plate part 11 has a surface 40 that faces the accommodating part 30. The metal substrate 10 has multiple depressions 41 and multiple projections 42 that are alternately arranged in the surface 40. The depressions 41 and the projections 42 are, for example, arranged at regular intervals in two directions that are parallel to the surface 40 and are perpendicular to each other. The depressions 41 and the projections 42 are disposed at least in a region that is part of the surface and that faces toward a semiconductor chip when the semiconductor chip is accommodated in the accommodating part 30. According to the example illustrated in FIG. 1A, the depressions 41 and the projections 42 are present in a first region 40a of the surface 40 and are absent in a second region 40b of the surface 40 surrounding the first region 40a. The depressions 41 and the projections 42 are formed by, for example, embossing a metal plate. That is, for example, the surface 40, more specifically, the first region 40a, is embossed with the depressions 41 and the projections 42. That is, the first region 40a is an embossed region and the second region 40b is a non-embossed region. Each of the projections 42 has a rectangular sectional shape and has a flat surface 42A at its top.

The plating layer 20 covers at least the surface of the flat plate part 11. The plating layer 20 includes, for example, a nickel (Ni) plating layer 21 contacting the surface 40 and a gold (Au) plating layer 22 on the nickel plating layer 21. The nickel plating layer 21 may cover the entirety of the metal substrate 10. The gold plating layer 22 covers at least the region that is part of the surface 40 and that faces toward a semiconductor chip when the semiconductor chip is accommodated in the accommodating part 30. That is, the gold plating layer 22 covers at least a region of the surface 40 in which the depressions 41 and the projections 42 are disposed. According to the example illustrated in FIG. 1k, the nickel plating layer 21 covers the first region 40a and the second region 40b of the surface 40 and the gold plating layer 22 covers the first region 40a of the surface 40. Thus, the area of the gold plating layer 22 may be smaller than the area of the nickel plating layer 21 in a plan view, namely, in a view in a direction normal to the surface 40. For example, the thickness of the nickel plating layer 21 is, for example, approximately 2000 nm (2 μm) or more and approximately, 7000 nm (7 μm) or less, and the thickness of the gold plating layer 22 is, for example, approximately 70 nm or more and approximately 400 nm or less.

To manufacture the heat spreader 1, first, a flat metal plate is processed to make the metal substrate 10. The depressions 41 and the projections 42 may be, for example, embossed on the metal substrate 10. After making the metal substrate 10, the nickel plating layer 21 is formed on the entire surfaces of the metal substrate 10. Thereafter, the gold plating layer 22 is famed on part of the nickel plating layer 21.

### [b] Second Embodiment

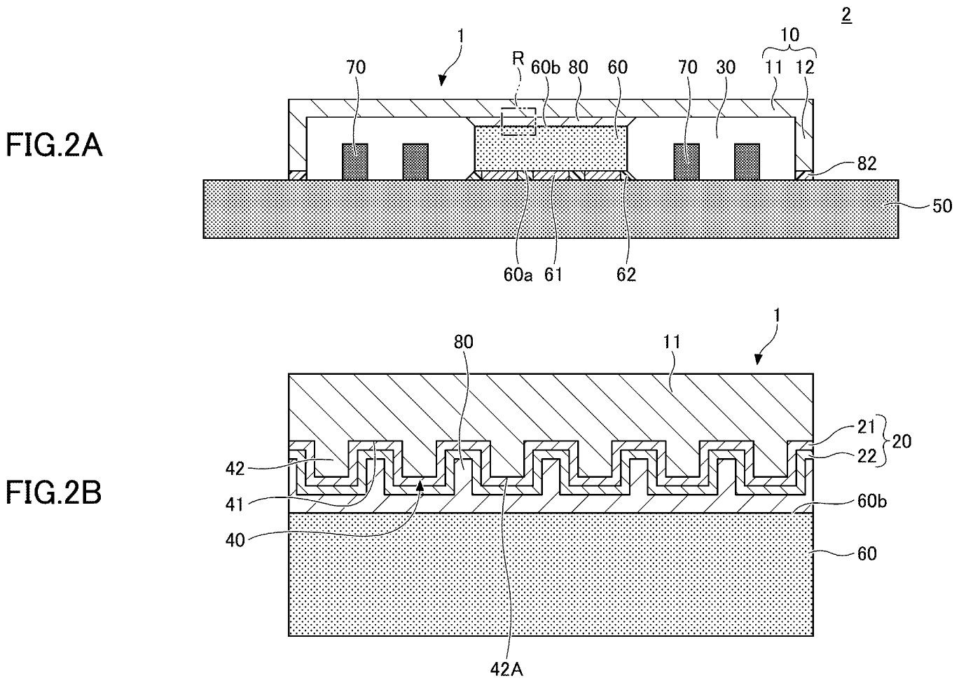

A second embodiment is described. The second embodiment relates to an electronic component device including the heat spreader 1 according to the first embodiment. FIG. 2A is a sectional view of the entirety of an electronic component device according to the second embodiment. FIG. 2B is an enlarged view of a region R in FIG. 2A.

Referring to FIG. 2A, an electronic component device 2 according to the second embodiment includes a wiring substrate 50, a semiconductor chip 60, capacitor elements 70, the heat spreader 1, and a metallic joining material 80.

Wiring layers (not depicted) are famed one on each side of the wiring substrate 50 and are interconnected via a multi-layer wiring layer (not depicted) including internal vias. According to the second embodiment, the heat spreader 1 is inverted relative to its orientation illustrated in the first embodiment.

Referring to FIG. 2A, the semiconductor chip 60 has connection terminals 61 provided on a lower surface 60a (facing toward the wiring substrate 50) of the semiconductor chip 60. The semiconductor chip 60 is flip-chip bonded to the wiring substrate 50. That is, the connection terminals 61 of the semiconductor chip 60 are connected to the pads of the wiring layer of the wiring substrate 50 at its upper surface. The gap under the semiconductor chip 60, namely, the gap between the lower surface 60a of the semiconductor chip 60 and the upper surface of the wiring substrate 50, is filled with an underfill resin 62. The semiconductor chip 60 is, for example, a central processing unit (CPU) chip that generates a large amount of heat. The semiconductor chip 60 is an example of an electronic component.

The capacitor elements 70 are mounted around the semiconductor chip 60 on the wiring substrate 50. In addition to the capacitor elements 70, a controller chip, a memory chip, etc., may be mounted.

The metallic joining material 80 joins the semiconductor chip 60 and the plating layer 20 of the heat spreader 1. More specifically, the metallic joining material 80 is in direct contact with a back surface 60b (the upper surface in FIGS. 2A and 2B) of the semiconductor chip 60 and the gold plating layer 22. The metallic joining material 80 contains, for example, indium (In). The metallic joining material 80 may be indium material.

Furthermore, the lower surface of the protruding part 12 of the heat spreader 1 and the upper surface of the wiring substrate 50 are bonded to each other by an adhesive 82.

To manufacture the electronic component device 2, the semiconductor chip 60 is mounted on the wiring substrate 50 by flip-chip bonding, and the gap between the semiconductor chip 60 and the wiring substrate 50 is filled with the underfill resin 62. Furthermore, the capacitor elements 70 are mounted on the wiring substrate 50.

Next, the exposed surface of the gold plating layer 22 is subjected to hydrophilic treatment such as fluxing, and a low-melting-point metallic material such as indium material is placed between the back surface 60b of the semiconductor chip 60 and the gold plating layer 22 of the heat spreader 1. Next, the low-melting-point metallic material is heated and cooled to be melted and solidified. At this point, part of the low-melting-point metallic material reacts with part of the gold plating layer 22 to generate an intermetallic compound, creating a strong intermetallic bond between the gold plating layer 22 and the metallic joining material 80 into which the low-melting-point metallic material is solidified. Furthermore, because the depressions 41 and the projections 42 are formed in the surface 40 of the metal substrate 10 that faces toward the semiconductor chip 60, the contact angle of the surface 40 is smaller because of hydrophilic treatment than in the case where the surface 40 is flat. Accordingly, the molten low-melting-point metallic material is easy to wet and spread over the surface 40, so that the semiconductor chip 60 and the heat spreader 1 are stably joined to each other by the metallic joining material 80. Solder or the like may also be used as the low-melting-point metallic material.

Furthermore, at the same time with the joining using the metallic joining material 80, the lower surface of the protruding part 12 of the heat spreader 1 and the upper surface of the wiring substrate 50 are bonded to each other using the adhesive 82.

In this manner, the electronic component device 2 can be manufactured.

According to the second embodiment, as described above, the molten low-melting-point metallic material is easy to wet and spread over the surface 40, and the semiconductor chip 60 and the heat spreader 1 can therefore be stably joined to each other by the metallic joining material 80. Furthermore, compared with the case where the surface 40 is flat, a large contact area between the metallic joining material 80 and the heat spreader 1 can achieve strong juncture. Furthermore, because the heat spreader 1 has the plating layer 20 and an intermetallic compound is formed from the plating layer 20 and the low-melting-point metallic material, strong juncture can be achieved.

The electronic component device 2 may be used for, for example, personal computers (PCs), game machines, automotive parts, power modules, etc.

The height of the projections 42 relative to the bottom of the depressions 41 is preferably 5 μm or more and 15 μm or less, more preferably, 7 μm or more and 13 μm or less, and still more preferably, 8 μm or more and 12 μm or less. If the height of the projections 42 is excessively small, the effect of reducing the contact angle or increasing the contact area may be reduced. If the height of the projections 42 is excessively large, air bubbles may be produced in the depressions 41.

Furthermore, the arithmetic average roughness (Ra) of the surface 40 is preferably 1.0 μm or more and 3.5 μm or less, more preferably, 1.3 μm or more and 3.2 μm or less, and still more preferably, 1.5 μm or more and 3.0 μm or less. If the arithmetic average roughness (Ra) of the surface 40 is excessively small, the effect of reducing the contact angle or increasing the contact area may be reduced. If the arithmetic average roughness (Ra) of the surface 40 is excessively large, air bubbles may be produced in the depressions 41.

All examples and conditional language provided herein are intended for pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority or inferiority of the invention. Although one or more embodiments of the present invention have been described in detail, it should be understood that the various changes, substitutions, and alterations could be made hereto without departing from the spirit and scope of the invention.

What is claimed is:

1. A heat spreader comprising:
a metal substrate having a surface in which a plurality of depressions and a plurality of projections are alternately arranged; and
a plating layer covering the surface.

2. The heat spreader as claimed in claim 1, wherein
the plating layer includes
a nickel plating layer contacting the surface; and
a gold plating layer on the nickel plating layer.

3. The heat spreader as claimed in claim 1, wherein each of the plurality of projections has a flat surface at a top of said each of the plurality of projections.

4. The heat spreader as claimed in claim 1, wherein a height of the plurality of projections relative to a bottom of the plurality of depressions is 5 μm or more and 15 μm or less.

5. The heat spreader as claimed in claim 1, wherein the surface has an arithmetic average roughness Ra of 1.0 μm or more and 3.5 μm or less.

6. The heat spreader as claimed in claim 1, wherein the metal substrate contains copper.

7. The heat spreader as claimed in claim 1, wherein the plurality of depressions and the plurality of projections are alternately arranged at regular intervals in two directions that are parallel to the surface and are perpendicular to each other.

8. The heat spreader as claimed in claim 1, wherein
the surface includes a first region and a second region surrounding the first region, and
the plurality of depressions and the plurality of projections are present in the first region and are absent in the second region.

9. The heat spreader as claimed in claim 1, wherein the surface is embossed with the plurality of depressions and the plurality of projections.

10. The heat spreader as claimed in claim 9, wherein
the surface includes
a first region embossed with the plurality of depressions and the plurality of projections; and
a second region surrounding the first region, the second region being a non-embossed region.

11. The heat spreader as claimed in claim 10, wherein
the plating layer includes
a nickel plating layer contacting the surface; and
a gold plating layer on the nickel plating layer,
the nickel plating layer covers the first region and the second region,
the gold plating layer covers at least the first region, and
an area of the gold plating layer is smaller than an area of the nickel plating layer in a plan view.

12. An electronic component device comprising:
a wiring substrate;
an electronic component on the wiring substrate;
the heat spreader as set forth in claim 1; and
a metallic joining material joining the electronic component and the plating layer of the heat spreader.
